(19) United States
(12) Patent Application Publication
(10) Pub. No.: US 2012/0007233 A1
(43) Pub. Date: Jan. 12, 2012

(54) SEMICONDUCTOR ELEMENT AND FABRICATION METHOD THEREOF

(75) Inventors: Kuei-Hsiao Kuo, Taichung (TW); Yi-Hsin Chen, Taichung (TW)

(73) Assignee: SILICONWARE PRECISION INDUSTRIES CO., LTD., Taichung (TW)

(21) Appl. No.: 12/893,052

(22) Filed: Sep. 29, 2010

(30) Foreign Application Priority Data
Jul. 12, 2010 (TW) 099122795

(51) Int. Cl. H01L 23/498; H01L 21/768

(52) U.S. Cl. 257/737; 438/124; 257/E23.068; 257/E21.589

(57) ABSTRACT

A semiconductor element and a fabrication method thereof. The method includes forming an encapsulating layer on a semiconductor silicon substrate having electrode pads and a passivation layer formed thereon, the encapsulating layer covering the electrode pads and a part of the passivation layer that surrounds the electrode pads; forming a covering layer on the passivation layer and the encapsulating layer with a plurality of openings that expose a part of the encapsulating layer; forming a bonding metallic layer on the part of the encapsulating layer that are exposed from the openings and electrically connecting the bonding metallic layer to the encapsulating layer, wherein the bonding metallic layer is not greater in diameter than the encapsulating layer; and forming a conductive element on the bonding metallic layer. The encapsulating layer provides a good buffering effect to prevent electrode pads from delamination or being broken caused by the direct stress from the conductive element.

### BACKGROUND OF THE INVENTION

1. Field of the Invention

The present invention relates to semiconductor elements and fabrication methods thereof, and more particularly, to a semiconductor element and a fabrication method thereof for preventing delamination of the electrode pads.

2. Description of Related Art

Along with the rapid development of electronics technology, electronic products are becoming lighter, thinner, shorter and smaller. There is a trend towards multi-function, high-frequency, and energy-saving electronic products. Conventionally, semiconductor chips are mounted in electronic products for controlling electric signals so as to make the electronic products work.

However, as the area of the active surface of the semiconductor chip is small, electronic pads that are mounted on the active surface must be formed thin and compact in size and could not be electrically connected to a printed circuit board directly. Alternatively, a semiconductor package substrate is served as an interface, and a fan out routing of the electrode pads in an electric-transmission manner is provided after mounting a plurality of semiconductor chips on the semiconductor package substrate, so the electric signals of the electrode pads of the semiconductor chip could expand outwardly to the area of the ball-placing side of the package substrate through the circuit layer of the semiconductor package substrate, so as to provide enough space between electrical connection pads of the area of the ball-placing side such that conductive elements (such as solder needles or solder balls) can mount on the electrical connection pads, and the semiconductor package substrate can be electrically connected to the printed circuit board of the electronic products via the conductive elements.

Nowadays, general semiconductor chips can be mounted on semiconductor package substrate in a flip-chip manner, to meet the demand for a complex signal transmission of electronic products with multi-function. By the above method, a plurality of conductive element are mounted between an active surface of semiconductor chip and a bump-placing side of semiconductor package substrate, and the two ends of the conductive element are connected to the electrode pads of the semiconductor chip and the bump pads of the semiconductor package substrate respectively. Thus, the semiconductor chip can electrically connect to the semiconductor package substrate, and then a encapsulating material is filled into a slit that is between the semiconductor chip and the semiconductor package substrate. However, there is a great difference among the respective coefficients of thermal expansion (CTE) of the semiconductor chip 10, the conductive element 12, the encapsulating material 14, and the semiconductor package substrate 16; as a result, delamination can easily occur between the conductive element 12 and the electrode pads 11 of the semiconductor chip 10. As shown in FIG. 1, the foregoing problems of delamination occurred in the semiconductor chip will increase gradually with reducing the line width, especially when the line width of the semiconductor chip is smaller than 90 nm, thereby adversely affecting the reliability and the electric transmission performance of the electronic products.

Therefore, the problem to be solved here is to provide a semiconductor element and fabrication method thereof which can prevent electrode pads from delamination or being broken caused by the direct stress arising from a mismatch of coefficient of thermal expansion (CTE) among the materials of the semiconductor element.

### SUMMARY OF THE INVENTION

In light of the above-mentioned drawbacks in the prior art, the present invention proposes a fabrication method of a semiconductor element, comprising the steps of providing a semiconductor silicon substrate having electrode pads and a passivation layer formed thereon, the passivation layer covering the semiconductor silicon substrate and one part of each of the electrode pads while the other part of each of the electrode pads being exposed from the passivation layer; forming an encapsulating layer that covers the electrode pads and a part of the passivation layer that surrounds the exposed part of each of the electrode pads; forming a covering layer on the passivation layer and the encapsulating layer, the covering layer having openings that expose a part of the encapsulating layer; and forming a bonding metallic layer on the part of the encapsulating layer that are exposed from the openings of the covering layer, and electrically connecting the bonding metallic layer to the encapsulating layer, wherein the bonding metallic layer is not greater in diameter than the encapsulating layer.

The fabrication method of the present invention further comprises forming a conductive element on the bonding metallic layer.

According to the aforementioned fabrication method, the present invention also proposes a semiconductor element, comprising: a semiconductor silicon substrate having a plurality of electrode pads and a passivation layer formed thereon, the passivation layer covering the semiconductor silicon substrate and one part of each of the electrode pads while the other part of each of the electrode pads being exposed from the passivation layer; an encapsulating layer covering the exposed part of each of the electrode pads and a part of the passivation layer surrounding the exposed part of each of the electrode pads; a covering layer formed on the passivation layer and the encapsulating layer, and having a plurality of openings for exposing a part of the encapsulating layer; and a bonding metallic layer formed on the exposed part of the encapsulating layer that are exposed from the opening of the covering layer, and electrically connecting to the encapsulating layer, wherein the bonding metallic layer is not greater in diameter than the encapsulating layer.

Moreover, the semiconductor element of the present invention further comprises a conductive element formed on the bonding metallic layer.

The semiconductor element and the fabrication method thereof for preventing delamination of the electrode pads as it mentioned above, in addition to the diameter of the bonding metallic layer being smaller than or equal to that of the encapsulating layer, the encapsulating layer can be a stack-layered structure and is made of at least a material selected from the group consisting of titanium, nickel, vanadium, copper and aluminum.

Specifically, the encapsulating layer is made of a material selected from the group consisting of titanium/nickel-vanadium alloy/copper (Ti/NiV/Cu), aluminum/nickel-vanadium alloy/copper (Al/NiV/Cu), titanium/aluminum (Ti/Al), and titanium/copper/nickel/copper (Ti/Cu/Ni/Cu).

In addition, the semiconductor silicon substrate can be a semiconductor chip or a wafer including a plurality of chips. The passivation layer can be a silicon nitride layer. The covering layer can be a dielectric layer made of benzo-cyclo-butene (BCB) or polyimide. The bonding metallic layer is an under bump metallurgy (UBM) layer.

Moreover, the conductive element comprises a solder material or a metal column formed on the bonding metallic layer and a solder material formed on the metal column.

Compared to the prior art, the semiconductor element and the fabrication method thereof in the present invention, an encapsulating layer is formed between the bonding metallic layer and the electrode pads, wherein the diameter of the encapsulating layer is larger than or equal to that of the metallic bonding layer, so as to provide a good buffering effect to avoid the great difference among the respective coefficients of thermal expansion (CTE) from the semiconductor silicon substrate, the electrode pads, the encapsulating material, and the conductive element during a period when the semiconductor element is being heated, which can lead to the electrode pads from delamination or being broken caused by the direct stress from the conductive element.

### BRIEF DESCRIPTION OF THE DRAWINGS

FIG. 1 (PRIOR ART) is a cross-sectional view showing delamination of electrode pads in the situation that semiconductor chip is mounted on a semiconductor package substrate;

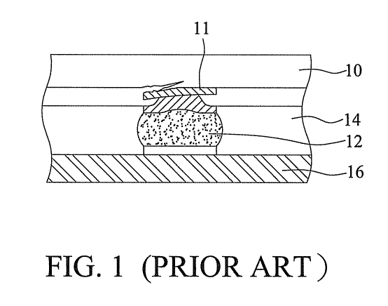

FIGS. 2A to 2E are schematic diagrams of a semiconductor element and a method for fabricating the same according to the present invention; and

FIG. 2E′ is a cross-sectional view showing a conductive element comprising a metal column and a solder material formed on the metal column.

### DETAILED DESCRIPTION OF THE PREFERRED EMBODIMENTS

The following illustrative embodiments are provided to illustrate the disclosure of the present invention. However, it should be understood that the scope of the invention is not limited to the disclosed embodiments.

For expository purpose, the drawings showing embodiments of the structure are semi-diagrammatic and not to scale and, particularly, some of the dimensions are for the clarity of presentation and are shown greatly exaggerated in the drawing FIGS. Similarly, although the views in the drawings for ease of description generally show similar orientations, this depiction in the FIGS. is arbitrary for the most part. Generally, the invention can be operated in and orientation. Likewise, terms, such as “on”, “above”, “bottom”, “top”, “over”, “under”, and “a/an”, are given to provide a thorough understanding of the invention. The present invention can also be performed or applied by other different embodiments. The details of the specification may be on the basis of different points and applications, and numerous modifications and variations can be devised without departing from the spirit of the present invention.

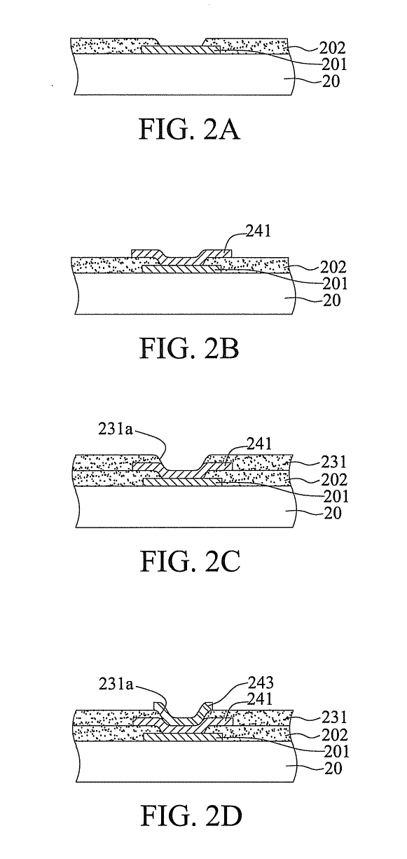

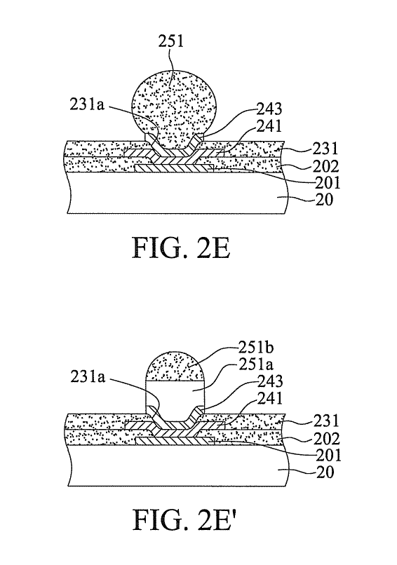

Please refer to FIGS. 2A through 2E, which are cross-sectional schematic diagrams of a semiconductor element and a fabrication method thereof of the present invention.

As shown in FIG. 2A, a semiconductor silicon substrate 20 is provided, and a plurality of electrode pads 201 and a passivation layer 202 are formed on the semiconductor silicon substrate 20 (a single electrode pad 201 is illustrated here). The semiconductor silicon substrate 20 is a semiconductor chip or a wafer including a plurality of chips. A passivation layer 202 covers the semiconductor silicon substrate 20 and one part of each of the electrode pads 201 while the other part of each of the electrode pads 201 being exposed from the passivation layer 202, and a plurality of openings are formed on the passivation layer 202 that exposes a part of each of the electrode pads 201. The passivation layer 202 is made of silicon nitride and is used to protect the semiconductor silicon substrate 20.

As shown in FIG. 2B, an encapsulating layer 241 is directly formed on the exposed part of each of the electrode pads 201, and is electrically connected to the electrode pads 201, so as to cover the exposed part of each of the electrode pads 201 and a part of the passivation layer 202 surrounding the exposed part of each of the electrode pads 201. The encapsulating layer 241 has a stack-layered structure and is made of at least a material selected from the group consisting of titanium, nickel, vanadium, copper and aluminum. Specifically, the encapsulating layer 241 is made of a material selected from the group consisting of titanium/nickel-vanadium alloy/copper (Ti/NiV/Cu), aluminum/nickel-vanadium alloy/copper (Al/NiV/Cu), titanium/aluminum (Ti/Al), or titanium/copper/nickel/copper (Ti/Cu/Ni/Cu).

As shown in FIG. 2C, a covering layer 231 is formed on the passivation layer 202 and the encapsulating layer 241, and a plurality of openings 231a is formed on the covering layer 231 for exposing a part of the encapsulating layer 241. The covering layer is made of benzo-cyclo-butene or polyimide.

As shown in FIG. 2D, a bonding metallic layer 243 is formed on the exposed part of the encapsulating layer 241 that are exposed from the opening 231a of the covering layer 231, and is electrically connected to the encapsulating layer 241. The bonding metallic layer 243 is not greater in diameter than the encapsulating layer 241. Moreover, the bonding metallic layer 243 is an UBM (Under Bump Metallurgy) layer, and is made of at least a material selected from the group consisting of aluminum, nickel-vanadium, copper, and titanium.

As shown in FIG. 2E, a conductive element 251 is formed on the bonding metallic layer 243. The conductive element can be a ball-like solder material, as shown in FIG. 2E. Besides, the conductive element 251 also can comprises a metal column 251a formed on the bonding metallic layer 243 and a solder material 251b formed on the metal column 251a, as shown in FIG. 2E′.

Therefore, by the foregoing fabrication method, the present invention further discloses a semiconductor element, comprising a semiconductor silicon substrate 20 having a plurality of electrode pads 201 and a passivation layer 202 formed thereon, the passivation layer 202 covering the semiconductor silicon substrate 20 and one part of each of the electrode pads 201 while the other part of each of the electrode pads 201 being exposed from the passivation layer 202; an encapsulating layer 241 covering the exposed part of each of the electrode pads 201 and a part of the passivation layer 202 surrounding the exposed part of each of the electrode pads 201; a covering layer 231 formed on the passivation layer 202 and the encapsulating layer 241, and having a plurality of openings 231a for exposing a part of the encapsulating layer 241; and a bonding metallic layer 243 formed on the exposed part of the encapsulating layer 241 that are exposed from the opening 231a of the covering layer 231, and electrically connected to the encapsulating layer 241, wherein the bonding metallic layer 243 is not greater in diameter than the encapsulating layer 241. In addition, the semiconductor element further comprises a conductive element 251 formed on the bonding metallic layer 243.

In view of the above, the present invention includes adding an encapsulating layer between the bonding metallic layer and the electrode pads of the semiconductor element, wherein the diameter of the encapsulating layer is greater than or equal to that of the bonding metallic layer. Preferably, the encapsulating layer can be a layer-stacked structure which is made of a material selected form the group consisting of titanium/nickel-vanadium alloy/copper (Ti/NiV/Cu), aluminum/nickel-vanadium alloy/copper (Al/NiV/Cu), titanium/aluminum (Ti/Al), or titanium/copper/nickel/copper (Ti/Cu/Ni/Cu), so as to provide a good buffering effect to avoid the great difference among the respective coefficients of thermal expansion (CTE) from the semiconductor silicon substrate, the electrode pads, the encapsulating material, and the conductive element during a period when the semiconductor element is being heated, which can result in the electrode pads from delamination or being broken caused by the direct stress from the conductive element. The investigation result shows that compared to conventional semiconductor element that mounted on bonding metallic layer directly, the semiconductor element with encapsulating layer of the present invention can reduce the direct stress from the conductive element by 26.8%; thus, the stress tolerance of the semiconductor element can also be improved with decreasing the size of electrode pads.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabrication method of a semiconductor element, comprising the steps of:
providing a semiconductor silicon substrate having electrode pads and a passivation layer formed thereon, the passivation layer covering parts of the electrode pads and the semiconductor silicon substrate;
forming an encapsulating layer that covers the electrode pads and a part of passivation layer that surrounds the electrode pads;
forming a covering layer on the passivation layer and the encapsulating layer, the covering layer having at least an opening for exposing a part of the encapsulating layer; and
forming a bonding metallic layer on the part of the encapsulating layer that are exposed from the at least an opening of the covering layer, and electrically connecting the bonding metallic layer to the encapsulating layer,
wherein the diameter of the bonding metallic layer is not greater than that of the encapsulating layer.

2. The fabrication method of claim 1, wherein the encapsulating layer has stack-layered structure and is made of at least a material selected from the group consisting of titanium, nickel, vanadium, copper and aluminum.

3. The fabrication method of claim 2, wherein the encapsulating layer is made of a material selected from the group consisting of titanium/nickel-vanadium alloy/copper (Ti/NiV/Cu), aluminum/nickel-vanadium alloy/copper (Al/NiV/Cu), titanium/aluminum (Ti/Al), and titanium/copper/nickel/copper (Ti/Cu/Ni/Cu).

4. The fabrication method of claim 1, wherein the passivation layer is a silicon nitride layer.

5. The fabrication method of claim 1, wherein the covering layer is made of a material of benzo-cyclo-butene or polyimide.

6. The fabrication method of claim 1, further comprising forming a conductive element on the bonding metallic layer.

7. The fabrication method of claim 6, wherein the conductive element is made of a solder material or formed by a metal column formed on the bonding metallic layer and a solder material formed on the metal column.

8. The fabrication method of claim 1, wherein the bonding metallic layer is an under bump metallurgy layer (UBM).

9. The fabrication method of claim 1, wherein the semiconductor silicon substrate is a semiconductor chip or a wafer including a plurality of chips.

10. A semiconductor element comprising:
a semiconductor silicon substrate having a plurality of electrode pads and a passivation layer formed thereon, the passivation layer covering the semiconductor silicon substrate and one part of each of the electrode pads while the other part of each of the electrode pads being exposed from the passivation layer;
an encapsulating layer covering the exposed part of each of the electrode pads and a part of the passivation layer surrounding the exposed part of each of the electrode pads;
a covering layer formed on the passivation layer and the encapsulating layer, and having a plurality of openings for exposing a part of the encapsulating layer; and
a bonding metallic layer formed on the exposed part of the encapsulating layer that are exposed from the opening of the covering layer, and electrically connected to the encapsulating layer, wherein the bonding metallic layer is not greater in diameter than the encapsulating layer.

11. The semiconductor element of claim 10, wherein the encapsulating layer has a stack-layered structure and is made of at least a material selected from the group consisting of titanium, nickel, vanadium, copper and aluminum.

12. The semiconductor element of claim 11, wherein the encapsulating layer is made of a material selected from the group consisting of titanium/nickel-vanadium alloy/copper (Ti/NiV/Cu), aluminum/nickel-vanadium alloy/copper (Al/NiV/Cu), titanium/aluminum (Ti/Al), and titanium/copper/nickel/copper (Ti/Cu/Ni/Cu).

13. The semiconductor element of claim 10, wherein the passivation layer is a silicon nitride layer.

14. The semiconductor element of claim 10, wherein the covering layer is made of benzo-cyclo-butene or polyimide.

15. The semiconductor element of claim 10, further comprising a conductive element formed on the bonding metallic layer.

16. The semiconductor element of claim 15, wherein the conductive element is made of a solder material, or formed by a metal column formed on the bonding metallic layer and a solder material formed on the metal column.

17. The semiconductor element of claim 10, wherein the bonding metallic layer is an under bump metallurgy layer.

18. The semiconductor element of claim 10, wherein the semiconductor silicon substrate is a semiconductor chip or a wafer including a plurality of chips.
